(19) United States
(12) Patent Application Publication
(10) Pub. No.: US 2017/0295340 A1
(43) Pub. Date: Oct. 12, 2017

(54) PACKAGE WITH INTEGRATED INFRARED AND FLASH LEDS

(71) Applicant: Peel Technologies, Inc., Mountain View, CA (US)

(72) Inventors: Samyeer Suresh Metrani, Milpitas, CA (US); Yong Tian, Cupertino, CA (US)

(21) Appl. No.: 15/205,937

(22) Filed: Jul. 8, 2016

Related U.S. Application Data
(60) Provisional application No. 62/319,255, filed on Apr. 6, 2016.

(51) Int. Cl. H04N 5/44; H04N 5/33; H04N 5/225; H04N 5/235; H01L 33/58; H01L 25/16

(52) U.S. Cl. CPC H04N 5/4403; H01L 33/58; H01L 25/167; H04N 5/2256; H04N 5/2354; H04N 5/332; H04N 2005/4425; H04N 2005/4426

(57) ABSTRACT

Disclosed is an integrated LED package for a client device. The integrated LED package includes a flash LED chip, an IR LED chip, and an optional reflective element. The IR LED chip includes an IR LED that emits a cone of IR light, for example, to send commands to another client device such as a TV, to control the TV. The reflective element modifies the cone of IR light such that a TV positioned in front of the client device is likely to receive IR light emitted from the client device. The integrated LED package includes a common anode for both the flash LED and the IR LED. Thus, the integrated LED package may reduce its overall size in comparison to a LED package that does not include a common anode, e.g., the LED package includes a separate anode each for the flash LED and the IR LED.

### CROSS-REFERENCE TO RELATED APPLICATIONS

This application claims the benefit of priority to U.S. Provisional Application No. 62/319,255, filed Apr. 6, 2016, the content of which is incorporated herein by reference in its entirety for all purposes.

### BACKGROUND

### Field of Art

The disclosure relates generally to infrared (IR) light-emitting diodes (LEDs) and particularly to an integrated LED package.

### Description of the Related Art

Several types of smartphone devices use light emitting diodes (LEDs) to generate flash for a camera on the smartphone. The smartphone devices typically include one or two flash LEDs. One flash LED emits white-type light and a second flash LED emits amber-type light. Television (TV) remotes and TVs also use LEDs. Typically, a TV remote uses IR LEDs to send commands to a TV, for example, to turn on, switch channels, and turn off the TV. LEDs, including flash LEDs and IR LEDs, each include an anode and a cathode. When a voltage is applied across the anode and the cathode of an LED, the LED emits light, for example, white-type light, amber-type light, or IR light.

### SUMMARY

Disclosed by way of example embodiments is an integrated LED package for a client device, for example, a smartphone. The integrated LED package includes a flash LED chip, an IR LED chip, and an optional reflective element. The flash LED chip includes a flash LED that emits flash light, for example, for a camera of the client device. The IR LED chip includes an IR LED that emits a cone of IR light, for example, to send commands to another client device such as a TV, to control the TV. The reflective element modifies the cone of IR light such that a TV positioned in front of the client device is likely to receive IR light emitted from the client device. The integrated LED package includes a common anode for both the flash LED and the IR LED. Thus, the integrated LED package may reduce its overall size in comparison to a LED package that does not include a common anode, e.g., the LED package includes a separate anode each for the flash LED and the IR LED.

Additionally, a client device with the integrated LED package may emit both flash light and IR light from a single aperture in the client device. Using a single aperture in the client device is advantageous, for example, to reduce tooling costs in manufacturing the client device. Additionally, a client device such as a smartphone with the integrated LED package can emit IR signals to another target device in front of a user of the smartphone. The integrated LED package may include transistors or other types of drive circuitry to toggle the state of a flash LED or IR LED. Further, the client device can use software controls with the drive circuitry to toggle the LED states. Since the integrated LED package includes both a flash LED and IR LED, the integrated LED package may be used for night vision (or low light level) applications with client devices such as smartphones.

### BRIEF DESCRIPTION OF THE DRAWINGS

The disclosed embodiments have advantages and features which will be more readily apparent from the detailed description, the appended claims, and the accompanying figures (or drawings). A brief introduction of the figures is below.

FIG. 1A is a diagram of a LED module in a client device according to one embodiment.

FIG. 1B is a diagram of an IR LED aperture in a client device according to one embodiment.

FIG. 2A is a diagram of a LED module with flash LED packages according to one embodiment.

FIG. 2B is a diagram of a LED module with flash LED packages and an IR LED package according to one embodiment.

FIG. 2C is a diagram of a LED module with an integrated LED package according to one embodiment.

FIG. 3 is a diagram of a LED module in a client device in use with a second client device according to one embodiment.

FIG. 4 is a diagram of a layout of components of an integrated LED package according to one embodiment.

FIG. 5 is a diagram of electrode pads of the integrated LED package in FIG. 4 according to one embodiment.

FIG. 6A is a diagram of a circuit with separate power and drive signals for a flash LED and an IR LED according to one embodiment.

FIG. 6B is a diagram of a common cathode circuit with a flash LED and an IR LED according to one embodiment.

FIG. 6C is a diagram of a common anode circuit with a flash LED and an IR LED according to one embodiment.

### DETAILED DESCRIPTION

The Figures (FIGS.) and the following description relate to preferred embodiments by way of illustration only. It should be noted that from the following discussion, alternative embodiments of the structures and methods disclosed herein will be readily recognized as viable alternatives that may be employed without departing from the principles of what is claimed.

Reference will now be made in detail to several embodiments, examples of which are illustrated in the accompanying figures. It is noted that wherever practicable similar or like reference numbers may be used in the figures and may indicate similar or like functionality. The figures depict embodiments of the disclosed system (or method) for purposes of illustration only. One skilled in the art will readily recognize from the following description that alternative embodiments of the structures and methods illustrated herein may be employed without departing from the principles described herein.

### Example System Overview

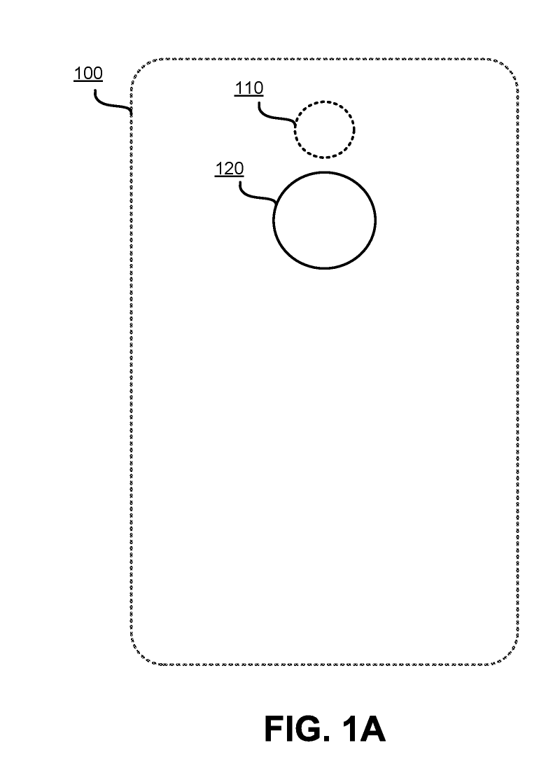

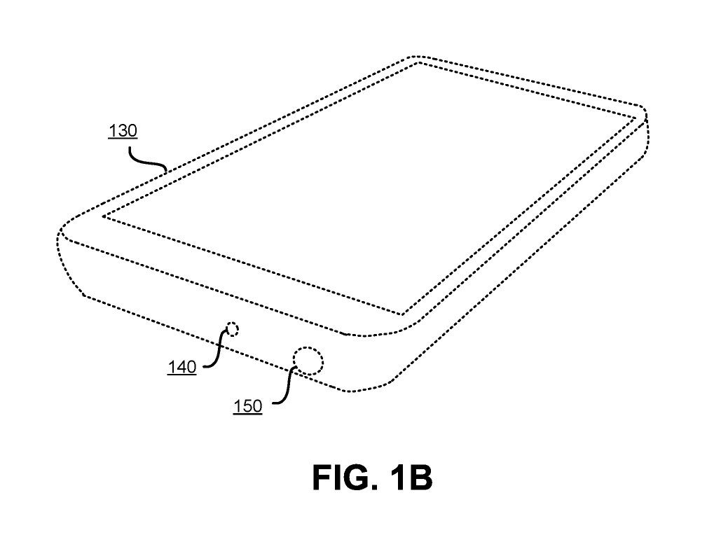

Figure (FIG.) IA is a diagram of a LED module in a client device 100 according to one embodiment. The client device 100 shown in FIG. 1A includes a camera 110 and a LED module 120. The client device 100 is an electronic device used by a user to perform functions such as executing software applications, consuming digital content, browsing websites hosted by web servers on a network, downloading files, and the like. For example, the client device 100 may be a smartphone, mobile device, a tablet, a remote control (e.g., for a television or digital video recorder) with a display screen, or a notebook. The camera 110 of the client device 100 is used to capture multimedia including images and videos. The LED module 120 includes a flash LED to provide a flash light for use in conjunction with the camera 110. In particular, when the client device 100 is in an environment with lower levels of lighting, the flash light provides additional lighting to improve the quality of an image captured by the camera 110. The client device 100 may also include other components, known to one skilled in the art, not illustrated in FIG. 1A for purposes of clarity. For instance, the client device 100 may include a microcontroller to control functions of the camera 110 and the LED module 120, e.g., providing an instruction to the LED module 120 to emit flash shortly before providing a coordinated instruction to the camera 110 to capture an image. In another example, the client device 100 has a time of flight sensor using an IR LED and a photodiode; the microcontroller implements algorithms for the time of flight sensor. In particular, the microcontroller records a timestamp corresponding to a time at which the IR LED emits an IR signal and a time at which the photodiode receives the IR signal (e.g., the IR signal reflected off an object back toward the client device 100). Based on the two timestamps, the microcontroller determines a time of flight of the IR signal. The microcontroller uses the time of flight, for example, to determine the proximity between the client device 100 and another object.

FIG. 1A illustrates a view of a backside (e.g., side opposite the primary screen side) of the client device 100. In an embodiment, the client device 100 is a smartphone and the camera 110 and LED module 120 are positioned on the backside of the client device 100. Thus, a user of the client device 100 is able to, e.g., take a photo of an object located behind the client device 100 while viewing a digital preview of the photo on a display on the front side of the client device 100. Typically, the camera 110 and LED package 120 are positioned toward an upper half of the client device 100, e.g., when vertically held, closer to a top portion and most likely the half of the client device 100 closer toward eyes of a user of the client device 100 relative to a vertical plane. This positioning of the camera 110 and LED package 120 provides an improved user experience to a user of the client device 100. In particular, this positioning allows the user to capture photos and/or videos more easily using the client device 100. In the embodiment shown FIG. 1A, the camera 110 is positioned above the LED module 120. However, in other embodiments, the camera 110 is positioned below, to the left, to the right, or in any other location relative to the LED module 120.

FIG. 1B is a diagram of an IR LED aperture in a client device 130 according to one embodiment. In some embodiments, the client device 130 is substantially the same as the client device 100 in FIG. 1A. FIG. 1B illustrates an isometric view of the client device 130, which includes an IR LED aperture 140 and an auxiliary port 150. In some embodiments, the client device 130 uses the IR LED aperture 140 only to emit IR light, e.g., from an IR LED next to the IR LED aperture 140. The client device 130 uses the auxiliary port 150, for example, to communicate with external devices such as headphones and other audio devices.

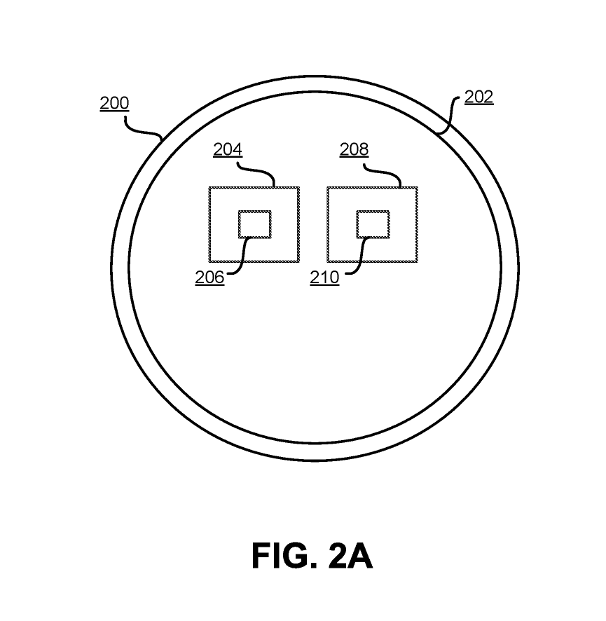

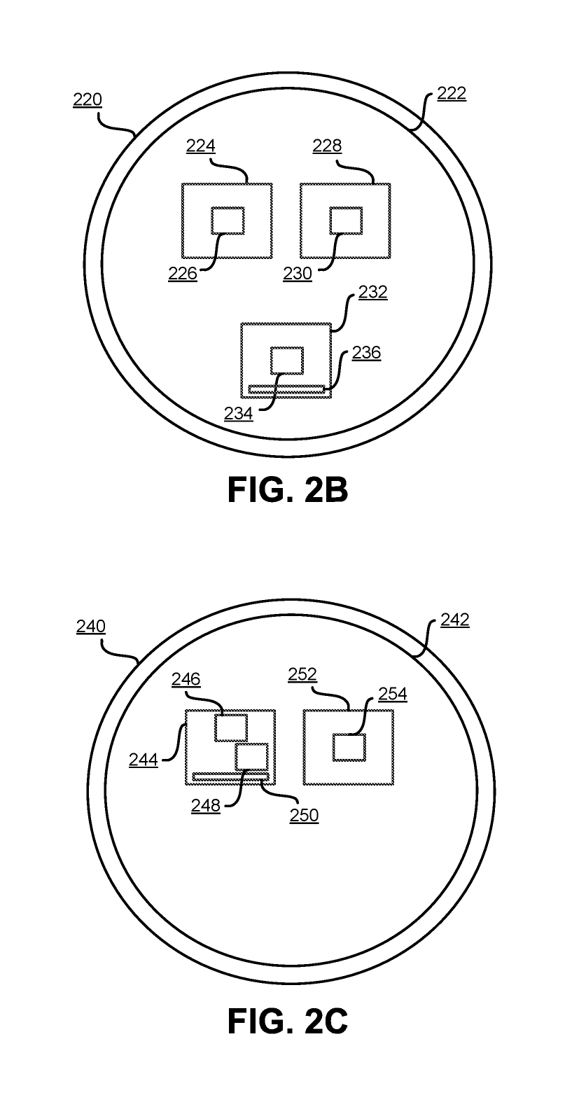

FIG. 2A is a diagram of a LED module 200 with flash LED packages according to one embodiment. In some embodiments, the LED module 200 is an embodiment of the LED module 120 in FIG. 1A. The LED module 200 shown in FIG. 2A includes a lens 202, a flash LED package 204 with a flash LED chip 206, and a flash LED package 208 with a flash LED chip 210. In an embodiment, the lens 202 is an optical medium that distorts light emitted from the LED module 200, e.g., the lens changes the angle of reflection of light emitted by the LED packages, i.e., 204 and 208, that passes through the lens 202. In other embodiments, the lens 202 does not distort light, or the LED module 200 does not necessarily include the lens 202.

In an example embodiment, the flash LED chip 206 includes an LED that emits white-type light. For instance, light that includes all wavelengths of visible light, e.g., electromagnetic radiation with wavelengths in a range of approximately 400 to 700 nanometers. Further, the flash LED chip 210 includes an LED that emits amber-type light, e.g., electromagnetic radiation with wavelengths in a range of approximately 580 to 590 nanometers. By including two types of flash LED chips, the LED module 200 can emit two types of flash light based on color temperatures of ambient lighting conditions of the LED module 200. Accordingly, a client device (e.g., client device 100 in FIG. 1) that includes the LED module 200 can capture images (e.g., with camera 110 in FIG. 1A) with improved image quality, e.g., because amber-type light is more suitable in conditions with lower levels of ambient lighting. In the embodiment shown in FIG. 2A, the flash LED package 204 is positioned on the left side of the LED module 200 and the flash LED package 208 is positioned on the right side of the LED module 200. In other embodiments, the flash LED package 204 and the flash LED package 208 are positioned in other arrangements in the LED module 200. In some embodiments, the client device 100 only includes one flash LED package, flash LED package 204 or flash LED package 208, in the flash LED module 200.

FIG. 2B is a diagram of a LED module 220 with flash LED packages and an IR LED package according to one example embodiment. In some example embodiments, the LED module 220 may be an embodiment of the LED module 120 in FIG. 1A. The LED module 220 includes a lens 222, a flash LED package 224 with a flash LED chip 226, a flash LED package 228 with a flash LED chip 230, and an IR LED package 232 with an IR LED chip 234 and a reflective element 236. The lens 222, flash LED package 224, flash LED chip 226, flash LED package 228, and flash LED chip 230 are substantially the same as, in FIG. 2A, the lens 202, flash LED package 204, flash LED chip 206, flash LED package 208, and flash LED chip 210, respectively. In some embodiments, the LED module 220 does not include, and does not require, the reflective element 236.

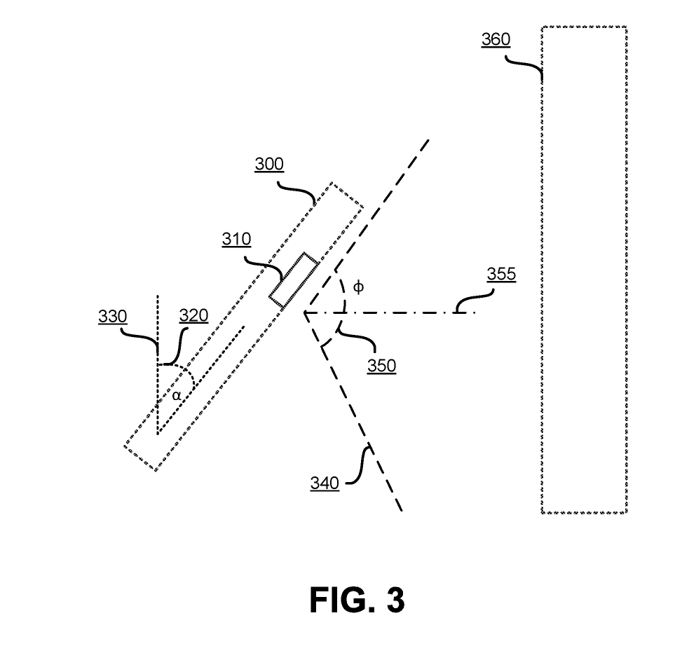

In an example embodiment, the IR LED chip 234 includes an IR LED that emits IR light. For instance, electromagnetic radiation with wavelengths in a range of approximately 750 nanometers to 1 millimeter. The reflective element 236 is, e.g., a mirror or any other material that reflects light including IR light. The reflective element 236 is positioned below the IR LED chip 234 so that IR light emitted from the IR LED chip 234 is reflected in an upward direction, e.g., toward the flash LED packages 224 and 228. The reflection of IR light is further described in FIG. 3. Typically, the IR LED chip 234 (e.g., a bare die of the IR LED chip 234) emits IR light at a wide angle. Thus, the reflective element 236 may be advantageous, e.g., because it focuses the IR light to a target angle, i.e., an angle smaller than the wide angle.

FIG. 2C is a diagram of a LED module 240 with an integrated LED package according to one example embodiment. In some example embodiments, the LED module 240 may be an embodiment of the LED module 120 in FIG. 1A. The LED module 240 includes a lens 242, an integrated LED package 244, and a flash LED package 252 with a flash LED chip 254. The integrated LED package 244 includes a flash LED chip 246, an IR LED chip 248, and a reflective element 250. In some embodiments, the LED module 240 does not necessarily include, and does not require, the flash LED package 252. That is, the LED module 240 includes only one LED package, e.g., the integrated LED package 244. The lens 242, flash LED chip 246, flash LED package 252, and flash LED chip 254 are substantially the same as, in FIG. 2A, the lens 202, flash LED chip 206, flash LED package 208, and flash LED chip 210, respectively. The IR LED chip 248 and reflective element 250 are substantially the same as, in FIG. 2B, the IR LED chip 234 and reflective element 236, respectively.

In contrast to the LED module 220 in FIG. 2B, LED module 240 has fewer components, while still being able to emit IR light. In particular, LED module 240 does not need an IR LED module (e.g., IR LED module 232) because the IR LED chip 248 and reflective element 250 are included in one of the flash LED packages. In FIG. 2C, the IR LED chip 248 and reflective element 250 are included flash LED package 244. However, in some embodiments, the IR LED chip 248 and reflective element 250 are included flash LED package 252 instead. Reducing the number of components in the LED module 240 may be advantageous, e.g., because the LED module 240 requires less time and/or resources to manufacture, the LED module 240 is more compact in size, and/or other advantages such reducing tooling costs for a client device including the LED module 240. In particular, since the LED module 240 can emit both flash light and IR light, a client device including the LED module 240 does not require separate apertures for each of a flash LED and an IR LED. For instance, the client device 130 shown in FIG. 1B would not require the aperture 140 if the client device 130 included the LED module 240.

### IR Cone of Light

FIG. 3 is a diagram of a LED module in a client device 300 in use with a second client device 360 according to one example embodiment. In some example embodiments, the client device 300 is an embodiment of the client device 100 in FIG. 1A. In the embodiment shown in FIG. 3, the client device 300 includes a LED module 310. In some embodiments, the LED module 310 is an embodiment of the LED module 220 in FIG. 2B or the LED module 240 in FIG. 2C.

In one example use case, the client device 300 is a smartphone client device of a user. Typically, users hold smartphone device at an angle α 320 offset from a vertical 330 to provide an improved field-of-view of a display of the smartphone from a user's eye level. For instance, the angle α 320 is approximately 30 to 40 degrees. A cone 340 of IR light emitted from an IR LED, e.g., the IR LED of IR LED chip 234 in FIG. 2B or the IR LED of IR LED chip 248 in FIG. 2C, has an associated beam width angle φ 350 of approximately 120 degrees in three-dimensional space (FIG. 3 illustrates a planar view of the cone 340 of IR light in two-dimensions). In other embodiments, the beam width angle φ 350 is approximately 60 degrees instead. Thus, an object within the range of the cone 340 of IR light may receive an IR signal emitted by an IR LED corresponding to the cone 340 of IR light. Due to a reflective element in the LED module 310, e.g., reflective element 236 in FIG. 2B or reflective element 250 in FIG. 2C, the cone 340 of IR light is angled closer toward the vertical 330. In contrast, without the reflective element, the centerline 355 of the beam width of the cone 340 would be approximately perpendicular to the smartphone client device. Thus, it is more likely that an object positioned in front of the client device 300, e.g., the second client device 360, may receive an IR signal emitted by an IR LED from the reflected cone 340 of IR light. In one embodiment, the angle α 320 is approximately 30 degrees, and thus the center line 355 is approximately 90 degrees offset relative to the vertical 330.

Following in the same example use case, the user uses the smartphone client device 300 with a second client 360, e.g., a TV client device. The user uses the smartphone to send commands to control the TV. In particular, the smartphone sends a command represented by an IR signal and the TV receives the IR signal. The command instructs the TV to, e.g., turn on, switch TV channels, adjust the volume level, turn off, and the like. Using the smartphone to send commands to control the TV is an advantage because the user does not need to use a separate TV remote to control the TV. In other embodiments, the smartphone can use the command for other applications, e.g., distance sensing, barcode generation, or IR QR (quick response) code generation.

### Integrated LED Package

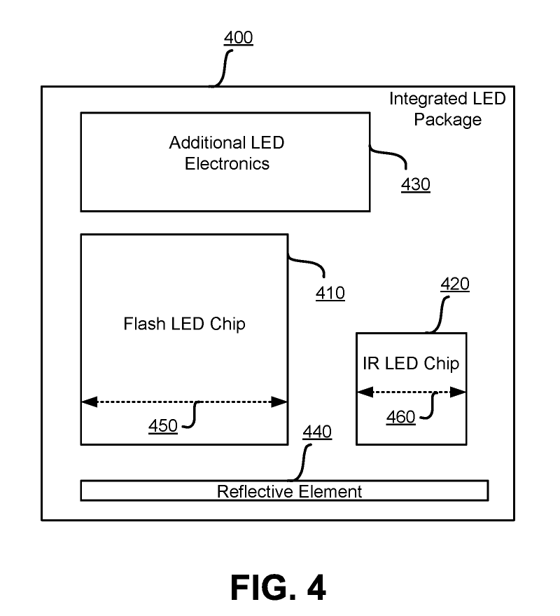

FIG. 4 is a diagram of a layout of components of an integrated LED package 400 according to one example embodiment. In some example embodiments, the integrated LED package 400 is an embodiment of the integrated LED package 244 in FIG. 2C. In the embodiment shown in FIG. 4, the integrated LED package 400 includes a flash LED chip 410, IR LED chip 420, additional LED electronics 430, and reflective element 440. The flash LED chip 410, IR LED chip 420, and reflective element 440 are substantially the same as, in FIG. 2C, the flash LED chip 246, IR LED chip 248, and reflective element 250, respectively. In an embodiment, the integrated LED package 400 is 2 millimeters by 1.6 millimeters, and may accommodate an 8 mil (i.e., thousandth of an inch) IR LED or a 14 mil IR LED. The dimension of the IR LED may indicate the length of an edge of a square die of the IR LED. In some embodiments, the integrated LED package 400 does not include, and does not require, the reflective element 440. In some embodiments, the additional LED electronics 430 include, e.g., electrostatic discharge protection circuits, metal oxide semiconductor field-effect transistors (MOSFET) for driving the flash LED chip 410 and/or the IR LED chip 420, Zener diodes, and/or other types of electronic components and circuits.

In one embodiment, the flash LED chip 410 has a dimension 450 of 0.95 mm. For example, the flash LED chip 410 is square-shaped with a side length of dimension 450. In one embodiment, the IR LED chip 420 has a dimension 460 of 0.51 mm. For example, the IR LED chip 420 is square-shaped with a side length of dimension 460.

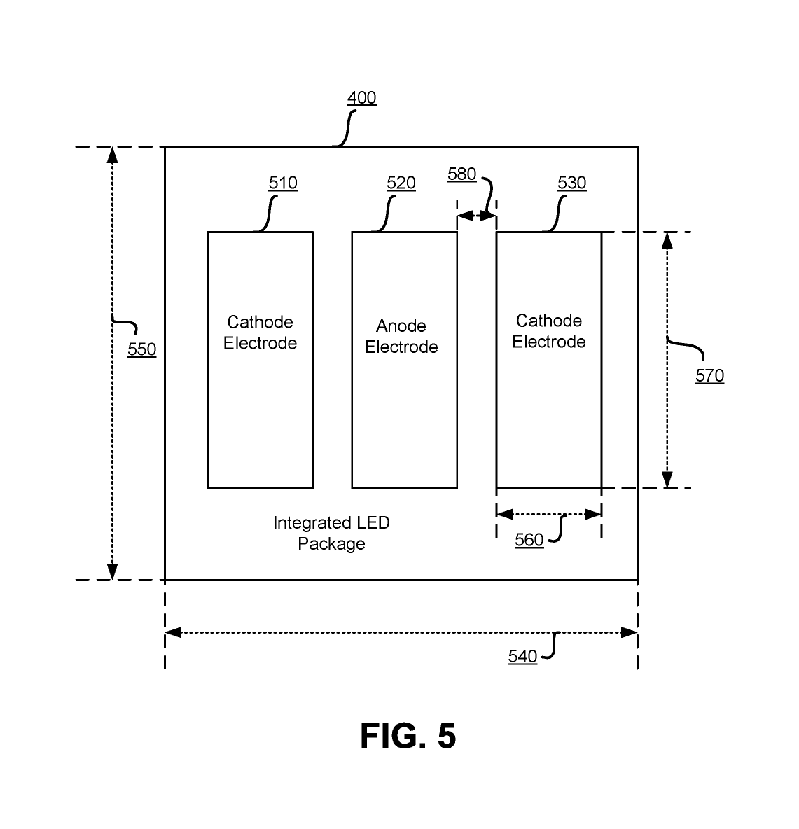

FIG. 5 is a diagram of electrode pads of the integrated LED package 400 in FIG. 4 according to one embodiment. In the embodiment shown in FIG. 5, the integrated LED package 400 includes a first cathode electrode 510, a common anode electrode 520, and a second cathode electrode 530. FIG. 5 illustrates a bottom view of the integrated LED package 400. Thus, the three electrodes are located on a bottom side of the integrated LED package 400. The common anode electrode 520 is connected to both an anode of the flash LED chip 410 and an anode of the IR LED chip 420. In an embodiment, the common anode electrode 520 provides an advantage because it reduces the need for two separate anodes, i.e., a first anode electrode for the flash LED chip 410 and a second anode electrode for the IR LED chip 420. Thus, a single electrode, i.e., the common anode electrode 520 may provide a voltage source to both the flash LED chip 410 and the IR LED chip 420. The integrated LED package 400 may be rectangular and have a width and length dimension. In one embodiment, the width dimension 540 is 2.04 mm and the length dimension 550 is 1.64 mm. In other embodiments, the width and length dimensions are different and each dimension is typically less than 5 mm.

In one embodiment, the first cathode electrode 510 corresponds to a cathode of the flash LED chip 410 and the second cathode electrode 530 corresponds to a cathode of the IR LED chip 420. In a different embodiment, the first cathode electrode 510 corresponds to the cathode of the IR LED chip 420 and the second cathode electrode 530 corresponds to the cathode of the flash LED chip 410. In the embodiment shown in FIG. 5, the cathode electrode 510 is positioned to the left of the common anode electrode 520, and a second cathode electrode 530 is positioned to the right of the common anode electrode 520. However, in other embodiments, the three electrodes may be positioned in any arrangement in the integrated LED package 400.

Each electrode may be rectangular and have a width and length dimension. For example, the cathode electrode 530 has a width dimension 560 and a length dimension 570. In one embodiment, the width dimension 560 is 0.5 mm and the length dimension 570 is 1.53 mm. In some embodiments, the anode electrode has a slightly smaller width dimension of 0.43 mm. In one embodiment, the space 580 between adjacent electrodes is 0.25 mm.

In some embodiments, the integrated LED package 400 includes a common cathode instead of a common anode. For example, the common cathode electrode 520 is connected to both the cathode of the flash LED chip 410 and the cathode of the IR LED chip 420. A first anode electrode 510 is connected to the anode of the flash LED chip 410, and a second anode electrode 530 is connected to the anode of the IR LED chip 420. In this example, the flash LED chip 410 and the IR LED chip 420 share a common trigger to emit light using the LEDs. Further, a voltage regulator may be used to control the drive signal for the flash LED chip 410 and the IR LED chip 420.

### Circuit Diagram

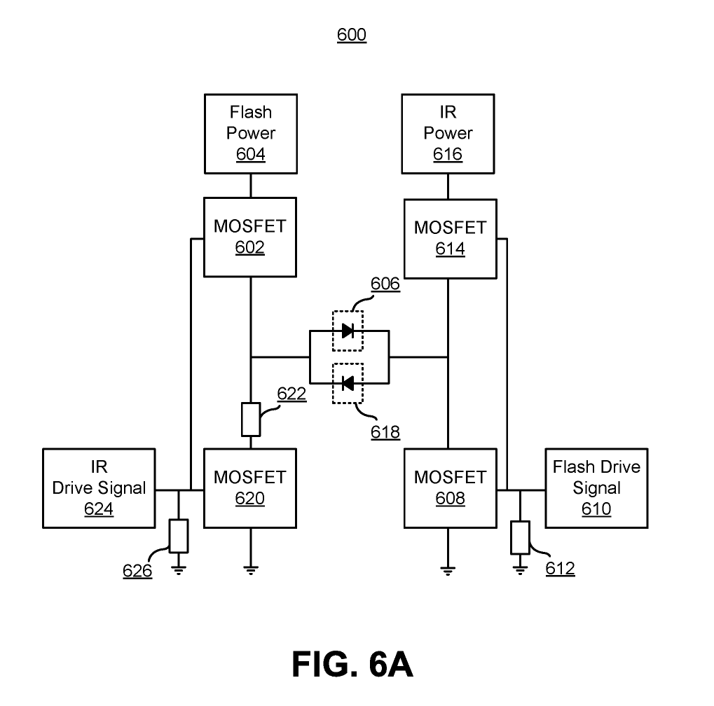

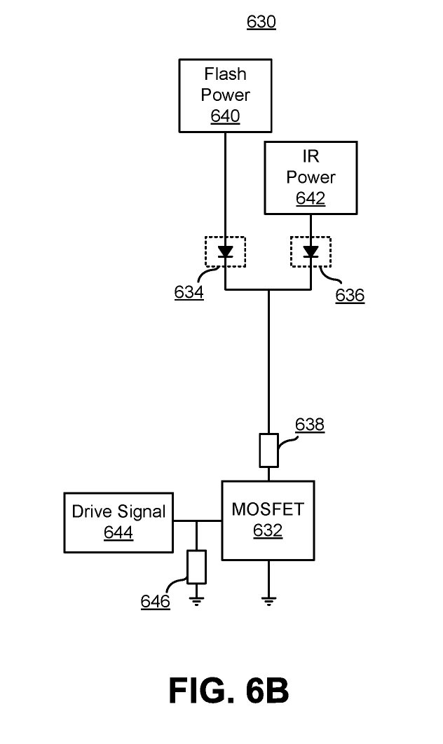

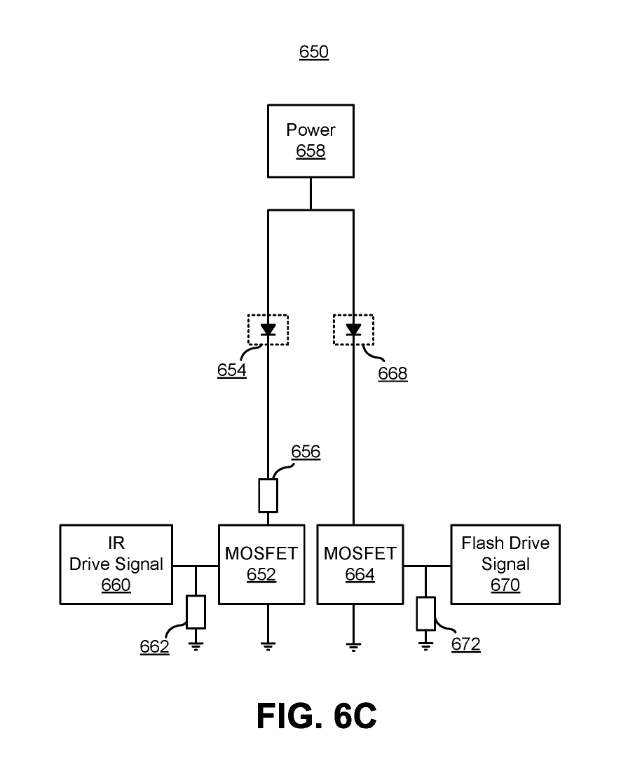

FIG. 6A is a diagram of a circuit 600 with separate power and drive signals for a flash LED and an IR LED according to one example embodiment. The circuit 600 includes a first metal-oxide-semiconductor field-effect transistor (MOSFET) 602 coupled to a source of flash power 604, for example, a high current rail (e.g., up to 1 ampere) typically included in a smartphone (e.g., the client device 100 shown in FIG. 1A). The first MOSFET 602 is coupled to the anode of a flash LED 606. The cathode of the flash LED 606 is coupled to a second MOSFET 608. The second MOSFET 608 is coupled to a flash drive signal 610 and grounded via a resistor 612. Using the first MOSFET 602 and the second MOSFET 608, the flash drive signal 610 can turn the flash LED 606 on or off.

The circuit 600 includes a third MOSFET 614 coupled to a source of IR power 616. The third MOSFET 614 is coupled to the anode of an IR LED 618. The cathode of the IR LED 618 is coupled to a fourth MOSFET 620 via a resistor 622. The fourth MOSFET 620 is coupled to an IR drive signal 624 and grounded via a resistor 626. Using the third MOSFET 614 and the fourth MOSFET 620, the IR drive signal 624 can turn the IR LED 618 on or off. In some embodiments, the MOSFETS 602 and 614 are P-channel type MOSFETS and the MOSFETS 608 and 620 are N-channel type MOSFETS. In other embodiments, the circuit 600 includes transistors of types other than P-channel and N-channel type MOSFETS.

The integrated LED package 244 shown in FIG. 2C may include the circuit 600 to control the flash LED chip 246 and the IR LED chip 248. In this case, the integrated LED package 244 includes a separate pin for each of the flash power 604, IR power 616, flash drive signal 610, IR drive signal 624, and ground. In some embodiments, the circuit 600 requires additional components (e.g., hardware components and/or software controls) to ensure that if the flash drive signal 610 and the IR drive signal 624 were simultaneously toggled, then the circuit 600 would not short the flash LED 606.

### Common Cathode Circuit

FIG. 6B is a diagram of a common cathode circuit 630 with a flash LED and an IR LED according to one embodiment. The circuit 630 includes a MOSFET 632 coupled to the cathode of a flash LED 634 and the cathode of an IR LED 636 via a resistor 638. The anode of the flash LED 634 is coupled to the flash power 640. The anode of the IR LED 636 is coupled to the IR power 642. The MOSFET 632 is also coupled to a drive signal 644 and grounded via the resistor 646. Using the MOSFET 632, the drive signal 644 can turn the flash LED 634 or the IR LED 636 on or off.

The integrated LED package 244 shown in FIG. 2C may include the circuit 630 to control the flash LED chip 246 and the IR LED chip 248. In this case, the integrated LED package 244 includes a separate pin for each of the flash power 640, IR power 642, drive signal 644, and ground. The flash LED 634 and the IR LED 636 share a common cathode, i.e., the cathode of the flash LED 634 is coupled to the cathode of the IR LED 636. Thus, to independently control the flash LED 634 and the IR LED 636, a client device including the integrated LED package 244 may require additional software controls to coordinate toggling (e.g., turning on or off) of the flash power 640 and IR power 642.

### Common Anode Circuit

FIG. 6C is a diagram of a common anode circuit 650 with a flash LED and an IR LED according to one embodiment. The circuit 650 requires less hardware than the circuit 600 shown in FIG. 6A and less software controls than the circuit 630 shown in FIG. 6B. Thus, the circuit 650 is a preferred embodiment compared to the circuits 600 and 630. The circuit 650 includes a first MOSFET 652 coupled to the cathode of an IR LED 654 via a resistor 656. The anode of the IR LED 654 is coupled to a source of power 658. The first MOSFET 652 is also coupled to an IR drive signal 660 and grounded via a resistor 662. The circuit 650 includes a second MOSFET 664 coupled to the cathode of a flash LED 668. The anode of the flash LED 668 is coupled to the source of power 658. The second MOSFET 664 is coupled to a flash drive signal 670 and grounded via a resistor 672. In some embodiments, the first MOSFET 652 and the second MOSFET 664 are N-channel type MOSFETS. In other embodiments, the circuit 650 includes different types of transistors other than MOSFETS, or other types of drive circuitry such as digital to analog converters (DAC) to control the level of intensity of light emitted by the flash LED.

The integrated LED package 244 shown in FIG. 2C may include the circuit 650 to control the flash LED chip 246 and the IR LED chip 248. In this case, the integrated LED package 244 includes a separate pin for each of the power 658, IR drive signal 660, flash drive signal 670, and ground. Thus, the circuit 650 requires a fewer number of pins relative to the circuit 600 shown in FIG. 6A. Reducing the number of pins may help reduce the size and cost of the integrated LED package 244. Further, the circuit 650 is less complex than the circuit 600 because the circuit 650 includes only two MOSFETS while circuit 600 includes four MOSFETS.

The IR LED 654 and the flash LED 668 share a common anode, i.e., the anode of the IR LED 654 is coupled to the anode of the flash LED 668. In an embodiment, the power 658 is coupled to the anode electrode 520 shown in FIG. 5, the IR drive signal is coupled to the cathode electrode 510, and the flash drive signal 670 is coupled to the cathode electrode 530. Client devices typically include software controls (e.g., corresponding to the IR drive signal 660 and the flash drive signal 670) for the IR LED 654 and the flash LED 668. Thus, unlike a client device with the circuit 630 shown in FIG. 6B, to independently control the IR LED 654 and the flash LED 668, a client device with the circuit 650 does not require additional software controls. Accordingly, a client device with the circuit 650 is less complex, in terms of hardware components and/or software controls than a client device with the circuit 630 or the circuit 600. The circuit 650 differs from standard approaches used to control both flash LEDs and IR LEDs and provides the advantageous described above over the standard approaches.

### Additional Considerations

The integrated LED package as disclosed provides benefits and advantages that include reducing the amount of resources required to manufacture the integrated LED package and/or devices comprising the integrated LED package. In particular, the integrated LED package includes, at least, both a flash LED chip and an IR LED chip. Further, the flash LED chip and the IR LED chip share a common anode. Thus, an LED module comprising the integrated LED package may emit both flash light and IR light, while being more compact in size relative to a different LED module comprising a separate flash LED package and IR LED package.

In various embodiments, a hardware module may be implemented mechanically or electronically. For example, a hardware module may comprise dedicated circuitry or logic that is permanently configured (e.g., as a special-purpose processor, such as a field programmable gate array (FPGA) or an application-specific integrated circuit (ASIC)) to perform certain operations. A hardware module may also comprise programmable logic or circuitry (e.g., as encompassed within a general-purpose processor or other programmable processor) that is temporarily configured by software to perform certain operations. It will be appreciated that the decision to implement a hardware module mechanically, in dedicated and permanently configured circuitry, or in temporarily configured circuitry (e.g., configured by software) may be driven by cost and time considerations.

As used herein any reference to “one embodiment” or “an embodiment” means that a particular element, feature, structure, or characteristic described in connection with the embodiment is included in at least one embodiment. The appearances of the phrase “in one embodiment” in various places in the specification are not necessarily all referring to the same embodiment.

Some embodiments may be described using the expression “coupled” and “connected” along with their derivatives. For example, some embodiments may be described using the term “coupled” to indicate that two or more elements are in direct physical or electrical contact. The term “coupled,” however, may also mean that two or more elements are not in direct contact with each other, but yet still co-operate or interact with each other. The embodiments are not limited in this context.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

In addition, use of the “a” or “an” are employed to describe elements and components of the embodiments herein. This is done merely for convenience and to give a general sense of the invention. This description should be read to include one or at least one and the singular also includes the plural unless it is obvious that it is meant otherwise.

Upon reading this disclosure, those of skill in the art will appreciate still additional alternative structural and functional designs for an integrated LED package comprising, at least, both a flash LED chip and an IR LED chip through the disclosed principles herein. Thus, while particular embodiments and applications have been illustrated and described, it is to be understood that the disclosed embodiments are not limited to the precise construction and components disclosed herein. Various modifications, changes, and variations apparent to those skilled in the art may be made in the arrangement, operation, and details of the method and apparatus disclosed herein without departing from the spirit and scope defined in the appended claims.

1. A circuit comprising:
an integrated light-emitting diode (LED) package including:
a flash LED configured to emit flash light, the flash LED including a first anode and a first cathode;
an infrared (IR) LED configured to emit IR light, the IR LED including a second anode and a second cathode;
a common anode electrode coupled to the first anode and the second anode and further coupled to a power source of a smartphone device; and
a first transistor coupled to the second cathode and configured to receive a first control signal provided by the smartphone device for toggling a state of the IR LED, and wherein the IR LED is further configured to:
generate an IR control signal based at least in part on the first control signal; and
provide the IR control signal to a device different than the smartphone device.

2. The circuit of claim 1, wherein the integrated LED package further comprises a reflective element configured to modify an angle of reflectance of the emitted IR light from the integrated LED package.

3. The circuit of claim 2, wherein a beam width of the emitted IR light is approximately 120 degrees and a center line of the beam width is approximately 90 degrees offset from a vertical axis.

4. (canceled)

5. The circuit of claim 1, wherein the power source is a high current rail.

6. (canceled)

7. The circuit of claim 1, wherein the device is a television and the IR control signal instructs the television to turn on, turn off, change a channel, or change a level of volume.

8. The circuit of claim 1, wherein the circuit is configured for use in the smartphone device including a primary screen side and a backside opposite of the primary screen side, and wherein the flash LED is configured to emit flash light from the backside.

9. The circuit of claim 1, further comprising a second transistor coupled to the first cathode and configured to receive a second control signal for toggling a state of the flash LED.

10. The circuit of claim 9, wherein the first transistor and the second transistor are each N-channel type metal oxide semiconductor field-effect transistors.

11. A circuit comprising:
an integrated light-emitting diode (LED) package including:
a flash LED configured to emit flash light, the flash LED including a first anode and a first cathode;
an infrared (IR) LED configured to emit IR light, the IR LED including a second anode and a second cathode;
a single common cathode electrode coupled to the first cathode and the second cathode; and
a transistor coupled to the single common cathode electrode and configured to receive a control signal for toggling a state of at least one of the flash LED and the IR LED.

12. The circuit of claim 11, further comprising a reflective element configured to modify an angle of reflectance of the emitted IR light from the integrated LED package.

13. The circuit of claim 12, wherein a beam width of the emitted IR light is approximately 120 degrees and a center line of the beam width is approximately 90 degrees offset from a vertical axis.

14. The circuit of claim 11, wherein the control signal is provided by a smartphone device, wherein the first anode is coupled to a first power source of the smartphone device, and wherein the second anode is coupled to a second power source of the smartphone device.

15. The circuit of claim 14, wherein the first power source is a high current rail.

16. The circuit of claim 11, further comprising a resistor coupled to the transistor and coupled to the single common cathode electrode.

17. The circuit of claim 11, wherein the IR LED is 8 mil.

18. The circuit of claim 11, wherein a width dimension of the integrated LED package and a length dimension of the integrated LED package are each less than 5 millimeters.

19. A circuit comprising:
a flash LED configured to emit flash light, the flash LED including a first anode and a first cathode;
an infrared (IR) LED configured to emit IR light, the IR LED including a second anode and a second cathode;
a common anode electrode coupled to the first anode and the second anode, and further coupled to a power source of a smartphone device; and
a first transistor coupled to the second cathode and configured to receive a control signal provided by the smartphone device for toggling a state of the IR LED, and wherein the IR LED is further configured to:
generate an IR control signal based at least in part on the first control signal; and
provide the IR control signal to a device different than the smartphone device.

20. The circuit of claim 19, wherein the circuit is configured for use in the smartphone device including a primary screen side and a backside opposite of the primary screen side, and wherein the flash LED is configured to emit flash light from the backside.

21. The circuit of claim 19, wherein the device is a television and the IR control signal instructs the television to turn on, turn off, change a channel, or change a level of volume.

22. The circuit of claim 14, wherein the IR LED is further configured to:
generate an IR control signal based at least in part on the first control signal; and
provide the IR control signal to a device different than the smartphone device.
